(19) United States
(12) Patent Application Publication
(10) Pub. No.: US 2024/0266199 A1
(43) Pub. Date: Aug. 8, 2024

(54) ALIGNMENT APPARATUS AND METHOD OF ALIGNMENT USING THE SAME

(71) Applicant: Samsung Display Co., LTD., Yongin-si (KR)

(72) Inventor: Je Hyeon YOON, Yongin-si (KR)

(73) Assignee: Samsung Display Co., LTD., Yongin-si (KR)

(21) Appl. No.: 18/531,854

(22) Filed: Dec. 7, 2023

(30) Foreign Application Priority Data
Feb. 7, 2023 (KR) 10-2023-0016381

(51) Int. Cl. H01L 21/68; G06T 7/33; H01L 21/027

(52) U.S. Cl. CPC H01L 21/682; G06T 7/33; H01L 21/027; G06T 2207/30148

(57) ABSTRACT

An alignment apparatus includes a support substrate having a first alignment mark formed thereon, and a wafer mounted on the support substrate as aligned to the first alignment mark. The first alignment mark includes a first mark extending in a first direction, a second mark extending in a second direction and intersecting the first mark at a side of the first mark, and a third mark extending in the second direction and intersecting the first mark at another side of the first mark.

### CROSS-REFERENCE TO RELATED APPLICATION(S)

This application claims priority to and benefits of Korean patent application No. 10-2023-0016381 under 35 U.S.C. § 119(a), filed on Feb. 7, 2023, in the Korean Intellectual Property Office (KIPO), the entire contents of which are incorporated herein by reference.

### BACKGROUND

### 1. Technical Field

The disclosure generally relates to an alignment apparatus and a method of alignment using the same.

### 2. Description of the Related Art

With the development of information technologies, the importance of a display device which is a connection medium between a user and information increases. Accordingly, display devices such as a liquid crystal display device and a light emitting display device are increasingly used.

Recently, a Head Mounted Display Device (HMD) has been developed. The HMD is a display device which a user wears in the form of glasses or a helmet, thereby implementing Virtual Reality (VR) or Augmented Reality (AR), in which a focus is formed at a distance close to eyes.

A high-resolution light emitting display panel may be applied to the HMD. The high-resolution light emitting display panel may use a wafer as a substrate.

A display panel generally uses a glass as a substrate. Therefore, after a wafer is mounted on the glass, a high-resolution light emitting display panel may be formed.

### SUMMARY

Embodiments provide an alignment apparatus and a method for alignment using the same, which can align a wafer and a mask at a desired position by using an alignment mark formed on a glass.

In accordance with an aspect of the disclosure, an alignment apparatus may include a support substrate having a first alignment mark formed thereon, and a wafer mounted on the support substrate as aligned to the first alignment mark. The first alignment mark may include a first mark extending in a first direction, a second mark extending in a second direction and intersecting the first mark at a side of the first mark, and a third mark extending in the second direction and intersecting the first mark at another side of the first mark.

A distance between the second mark and the third mark may be less than a length of a flat zone of the wafer in the first direction.

A length of the first mark in the first direction may be greater than a length of a flat zone of the wafer in the first direction.

The alignment apparatus may further include a camera that photographs the first alignment mark and the wafer, and a controller that aligns a position of the wafer by using a photographed image of the camera.

The controller may move at least one of the wafer and the support substrate such that the second mark and the third mark overlap a flat zone of the wafer in the second direction.

The controller may move at least one of the wafer and the support substrate such that a distance between the second mark and a flat zone of the wafer and a distance between the third mark and the flat zone of the wafer are within a range and substantially the same.

The alignment apparatus may further include a mask including a second alignment mark. The controller may align a position of the mask by using the first alignment mark and the second alignment mark.

The second alignment mark may include a 2ath alignment mark that aligns with an area of the first mark and has a cross or a plus sign shape in a plan view, and a 2bth alignment mark that aligns with another area of the first mark and has a cross or a plus sign shape in a plan view.

The 2ath alignment mark may include first alignment keys located to surround the area of the first mark and a portion of the second mark in a plan view. The first alignment keys may have a “L” shape, a shape obtained by rotating the “L” shape by 90 degrees, a shape obtained by rotating the “L” shape by 180 degrees, and a shape obtained by rotating the “L” shape by 270 degrees in a plan view.

A distance between the first alignment keys in the first direction may be greater than a width of the second mark in the first direction, and a distance between the first alignment keys in the second direction may be greater than a width of the first mark in the second direction.

The 2bth alignment mark may include second alignment keys to be located to surround the another area of the first mark and a portion of the third mark in a plan view. The second alignment keys may have a “L” shape, a shape obtained by rotating the “L” shape by 90 degrees, a shape obtained by rotating the “L” shape by 180 degrees, and a shape obtained by rotating the “L” shape by 270 degrees in a plan view.

A distance between the second alignment keys in the first direction may be greater than a width of the third mark in the first direction, and a distance between the second alignment keys in the second direction may be greater than a width of the first mark in the second direction.

The alignment apparatus may further include a third alignment mark located at an upper side of a flat zone of the wafer.

The third alignment mark may include a 3ath alignment mark located at an upper side of the flat zone and having a cross or a plus sign shape in a plan view, and a 3bth alignment mark located at another upper side of the flat zone and having a cross or a plus sign shape in a plan view.

The controller may align the wafer by using a distance between the first alignment mark and the third alignment mark and positions of the first alignment mark and the third alignment mark.

In accordance with another aspect of the disclosure, a method of alignment may include aligning a position of a wafer by using a first alignment mark formed on a support substrate.

The first alignment mark may include a first mark extending in a first direction, a second mark extending in a second direction and intersecting the first mark at a side of the first mark, and a third mark extending in the second direction and intersecting the first mark at another side of the first mark.

After the aligning of the position of the wafer, a distance between a flat zone of the wafer and the first alignment mark may be within a range, and the second mark and the third mark may overlap the flat zone in the second direction.

A second alignment mark may be formed on the wafer. The position of the wafer may be aligned by using a distance between the first alignment mark and the second alignment mark and positions of the first alignment mark and the second alignment mark.

A mask used in a processing process of the wafer may be provided. The method may further include printing a third alignment mark on the mask, and aligning a position of the mask by using the first alignment mark and the third alignment mark.

The method may further include photographing the first alignment mark and the wafer by using a camera.

### BRIEF DESCRIPTION OF THE DRAWINGS

Embodiments will now be described more fully hereinafter with reference to the accompanying drawings; however, they may be embodied in different forms and should not be construed as limited to the embodiments set forth herein. Rather, these embodiments are provided so that this disclosure will be more thorough and complete, and will fully convey the scope of the embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a view illustrating an alignment apparatus in accordance with an embodiment of the disclosure.

FIG. 2 is a view illustrating an embodiment of a first alignment mark shown in FIG. 1.

FIGS. 3A to 3C are views illustrating an alignment process of a wafer using the first alignment mark.

FIGS. 4 and 5 are views illustrating a process of aligning a mask by the alignment apparatus in accordance with an embodiment of the disclosure.

FIG. 6 is a view illustrating a second alignment mark printed on the mask.

FIG. 7 is a view illustrating an alignment apparatus in accordance with an embodiment of the disclosure.

FIGS. 8A to 8C are views illustrating an alignment process of a wafer using a first alignment mark and a third alignment mark.

### DETAILED DESCRIPTION OF THE EMBODIMENTS

Hereinafter, embodiments are described in detail with reference to the accompanying drawings so that those skilled in the art may readily practice the disclosure. The disclosure may be implemented in various different forms and is not limited to the embodiments described in the specification.

A part irrelevant to the description will be omitted to clearly describe the disclosure, and the same or similar constituent elements will be designated by the same reference numerals throughout the specification. Therefore, the same reference numerals may be used in different drawings to identify the same or similar elements.

In addition, the size and thickness of each component illustrated in the drawings are arbitrarily shown for better understanding and ease of description, but the disclosure is not limited thereto. Thicknesses of several portions and regions are exaggerated for clear expressions.

In description, the expression “equal” may mean “substantially equal.” That is, this may mean equality to a degree to which those skilled in the art can understand the equality. Other expressions may be expressions in which “substantially’ is omitted.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

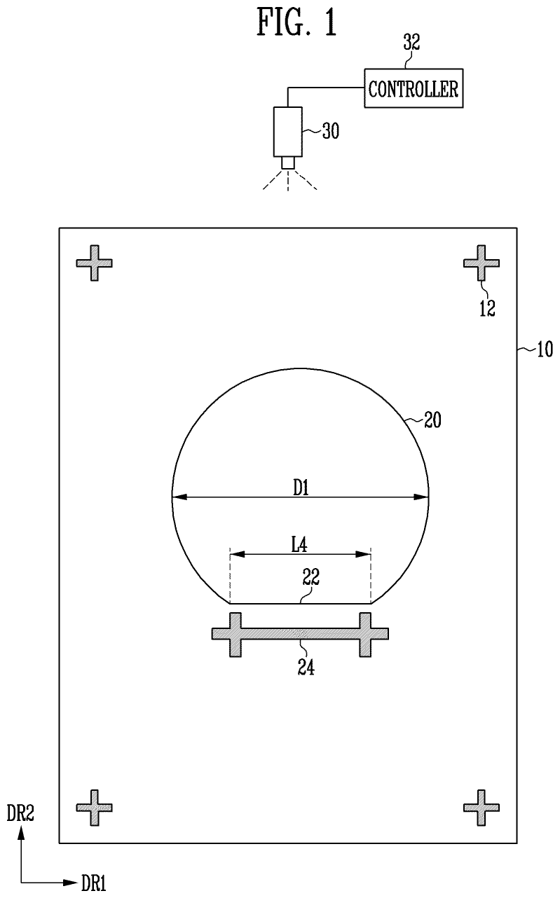

FIG. 1 is a view illustrating an alignment apparatus in accordance with an embodiment of the disclosure. In FIG. 1, only portions necessary for description of the disclosure in the alignment apparatus will be illustrated.

Referring to FIG. 1, the alignment apparatus in accordance with the embodiment of the disclosure may include a glass 10 (or support substrate), a wafer 20, a camera 30, and a controller 32.

In general, a manufacturing apparatus of a display device may manufacture a display panel by using the glass 10. For example, the display panel may be manufactured by sequentially stacking a transistor layer, a light emitting layer, and a cover layer on the glass 10. To this end, the size of a chamber included in an equipment, e.g., a deposition apparatus, used for the manufacturing apparatus, may be manufactured suitable for the size of the glass 10. In an embodiment of the disclosure, the glass 10 maybe used as a support part (or support substrate) on which the wafer 20 is mounted.

A fixed alignment mark 12 maybe formed on the glass 10. For example, the fixed alignment mark 12 maybe formed on a side of the glass 10. For example, the fixed alignment mark 12 maybe formed at a corner portion of the glass 10, and four fixed alignment marks 12 maybe formed corresponding to the rectangular glass 10. The fixed alignment mark 12 may 12 maybe used to align a position of the glass 10 in a processing process.

A first alignment mark 24 maybe formed on the glass 10. The first alignment mark 24 may be formed at a lower side of a central portion of the glass 10. The first alignment mark 24 may be used to align the wafer 20.

The wafer 20 maybe mounted (or fixed) on the glass 10 such that a flat zone 22 is located adjacent to the first alignment mark 24. The alignment apparatus in accordance with the embodiment of the disclosure may control an arrangement of the wafer 20 and the glass 10 such that the wafer 20 is aligned at a desired position by using the first alignment mark 24.

A transistor layer, a light emitting layer, and a cover layer may be sequentially stacked on the wafer 20 as the wafer 20 goes through processing processes after the wafer 20 is fixed at the desired position. Various other layers currently available in the art, in addition to the transistor layer, the light emitting layer, and the cover layer, may be stacked on the wafer 20.

For example, a filter layer may be formed between the light emitting layer and the cover layer such that only light of a desired color is emitted.

The wafer 20 maybe fixed to the glass 10 after aligned to the first alignment mark 24. For example, the alignment apparatus may align the wafer 20 such that a distance between the flat zone 22 of the wafer 20 and the first alignment mark 24 is substantially constant.

The camera 30 may photograph the first alignment mark 24 and the wafer 20, and supply a photographed image to the controller 32. The camera 30 maybe selected from various cameras currently available in the art, including a CCD camera.

The controller 32 may decide the position of the wafer 20 by using the photographed image, and change the position of the wafer 20 and/or the glass such that the wafer 20 is aligned at a position (predetermined or selectable).

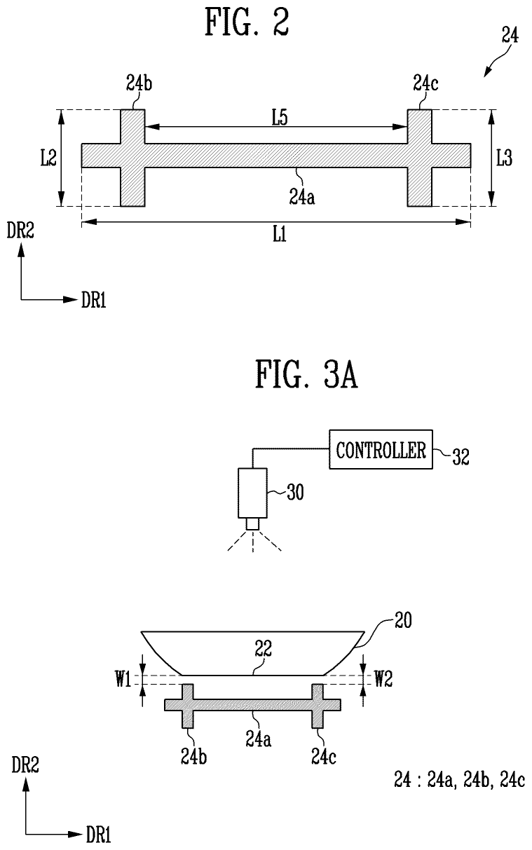

FIG. 2 is a view illustrating an embodiment of the first alignment mark shown in FIG. 1.

Referring to FIG. 2, the first alignment mark 24 may include a first mark 24a extending in a first direction DR1,and a second mark 24b and a third mark 24c, which extend in a second direction DR2 intersecting the first direction DR1.

The first mark 24a may have a horizontal bar shape extending in the first direction DR1. The first direction DR1 may be a horizontal direction (or a vertical direction) of the glass 10. In an embodiment, a length L1 of the first mark 24a in the first direction DR1 may be shorter than a diameter D1 of the wafer 20. In an embodiment, the length L1 of the first mark 24a in the first direction DR1 may be longer than a length L4 of the flat zone 22 of the wafer 20 in the first direction D1.

The second mark 24b may have a vertical bar shape extending in the second direction DR2. The second direction DR2 may be a vertical direction (or the horizontal direction) of the glass 10. The second mark 24b may be located at (or adjacent to) a side of the first mask 24a to intersect the first mark 24a. For example, the second mark 24b may be located at a left side of the first mark 24a to intersect the first mark 24a. A portion at which the first mark 24aand the second mark 24b intersect each other may have a cross or a plus sign shape in a plan view. A length of the second mark 24b in the second direction DR2 may be shorter than the length L4 of the flat zone 22.

The third mark 24c may have a vertical bar shape extending in the second direction DR2. The third mark 24c may be located at (or adjacent to) another side of the first mark 24ato intersect the first mark 24a. For example, the third mark 24c may be located at a right side of the first mark 24a to intersect the first mark 24a. A portion at which the first mark 24a and the third mark 24c intersect each other may have a cross or a plus sign shape in a plan view. A length L3 of the third mark 24c in the second direction DR2 may be shorter than the length L4 of the flat zone 220.

The second mark 24b and the third mark 24c may overlap the flat zone 22 of the wafer 20 in the second direction DR2. To this end, a distance L5 between the second mark 24b and the third mark 24c may be shorter than the length L4 of the flat zone 22.

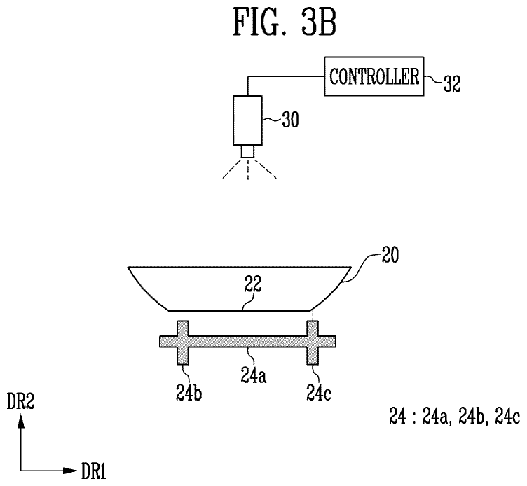

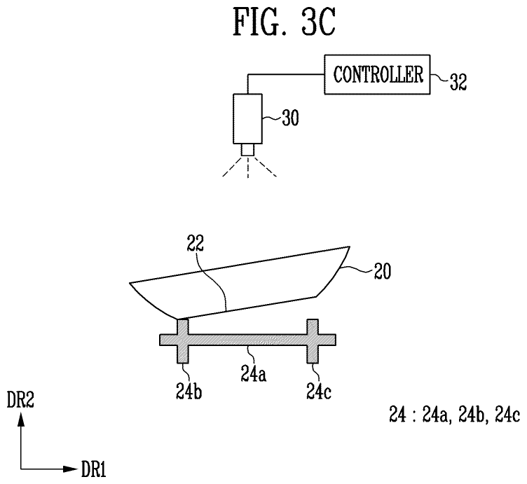

FIGS. 3A to 3C are views illustrating an alignment process of the wafer using the first alignment mark. For convenience of description, only a portion of the wafer 20 is illustrated in FIGS. 3A to 3C.

Referring to FIGS. 3A to 3C, the wafer 20 maybe mounted on the glass 10 aligned to the first alignment mark 24. After the wafer 20 is mounted on the glass 10, it may be decided that the wafer 20 has been mounted at a desired position by using the camera 30. In an embodiment, the camera 30 may photograph the first alignment mark 24 and the wafer 20, and supply a photographed image to the controller 32. The controller 32 may decide that the flat zone 22 of the wafer 20 and the second and third marks 24b and 24c are completely overlap with each other in the second direction DR2.

For example, in case that the flat zone 22 and the third mark 24c do not completely overlap with each other in the second direction DR2 as shown in FIG. 3B, the controller 32 may decide that the wafer 20 is not mounted at the desired position. The controller 32 may move the wafer 20 (or the glass 10) such that the flat zone 22 and the second and third marks 24b and 24c completely overlap with each other in the second direction DR2. For example, a moving mean (not shown) may move the wafer 20 and/or the glass 10. In case that the flat zone 22 and the second and third marks 24b and 24c completely overlap with each other in the second direction DR2, the controller 32 may decide that the wafer 20 is aligned at the desired position in the first direction DR1.

In an embodiment, the camera 30 may photograph the first alignment mark 24 and the wafer 20, and supply a photographed image to the controller 32. The controller 32 may decide whether a distance (or width) W1 between the second mark 24b and the flat zone 22 and a distance W2 between the third mark 24c and the flat zone 22 are within a desired range.

For example, in case that the flat zone 22 overlaps the second mark 24b (or the third mark 24c) as shown in FIG. 3C, the controller 32 may decide that the wafer 20 is not aligned at the desired position. For example, in case that the distance W1 between the second mark 24band the flat zone 22 and the distance W2 between the third mark 24c and the flat zone 22 are not within the desired range, the controller 32 may decide that the wafer 20 is not aligned at the desired position. In an embodiment, in case that the distance W1 between the second mark 24b and the flat zone 22 and the distance W2 between the third mark 24c and the flat zone 22 are different from each other, the controller 32 may decide that the wafer 20 is not mounted at the desired position.

In an embodiment, the controller 32 may move the wafer 20 (or the glass 10) such that the distance W1 between the second mark 24b and the flat zone 22 and the distance W2 between the third mark 24c and the flat zone 22 are within the desired range while being substantially the same. In case that the distance W1 between the second mark 24b and the flat zone 22 and the distance W2 between the third mark 24c and the flat zone 22 are within the desired range while being substantially the same, the controller 32 may decide that the wafer 20 is aligned at the desired position in the second direction DR2.

In the above-described embodiment of the disclosure, the wafer 20 maybe aligned in the first direction DR1 using whether the second and third marks 24b and 24c and the flat zone 22 overlap with each other. The wafer 20 maybe aligned in the second direction DR2 using the distances W1 and W2 between the second and third marks 24b and 24c and the flat zone 22. For example, in the embodiment of the disclosure, the position of the wafer 20 in the first direction DR1 and the second direction DR2 may be aligned using the first alignment mark 24, and accordingly, the wafer 20 maybe fixed at the desired position.

A transistor layer, a light emitting layer, a cover layer, and the like may be formed on the wafer 20 as the wafer 20 goes through various processes (e.g., a deposition process, a photo process, an etching process, and the like) after the wafer 20 is fixed to the glass 10.

In an embodiment, an organic material, an inorganic material, a conductive material, and the like may be deposited on the wafer 20 by using multiple masks to form the transistor layer. In an embodiment, a light emitting material and the like may be deposited on the wafer 20 by using multiple masks to form the light emitting layer. Therefore, the alignment apparatus may need to perform a process of aligning a mask. In an embodiment of the disclosure, the alignment apparatus may be one of apparatuses (e.g., a deposition apparatus, and the like) used in a processing process.

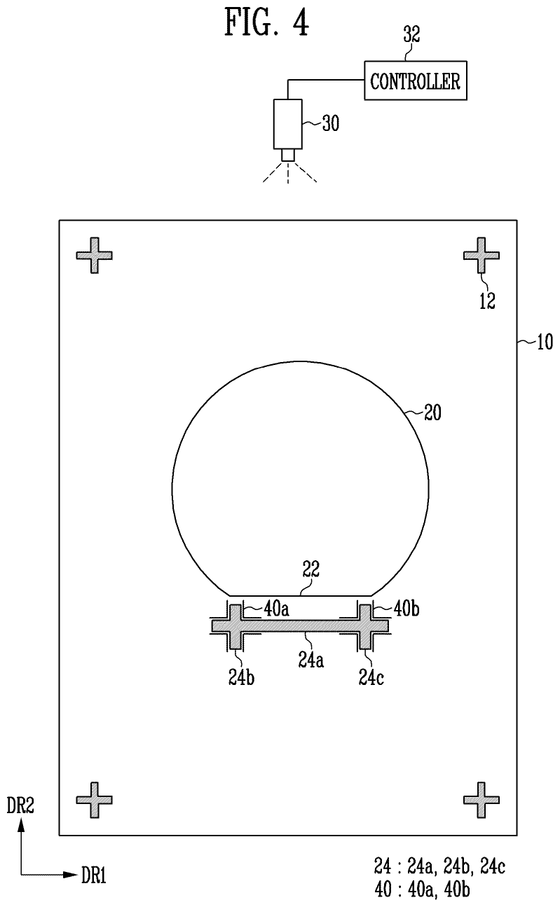

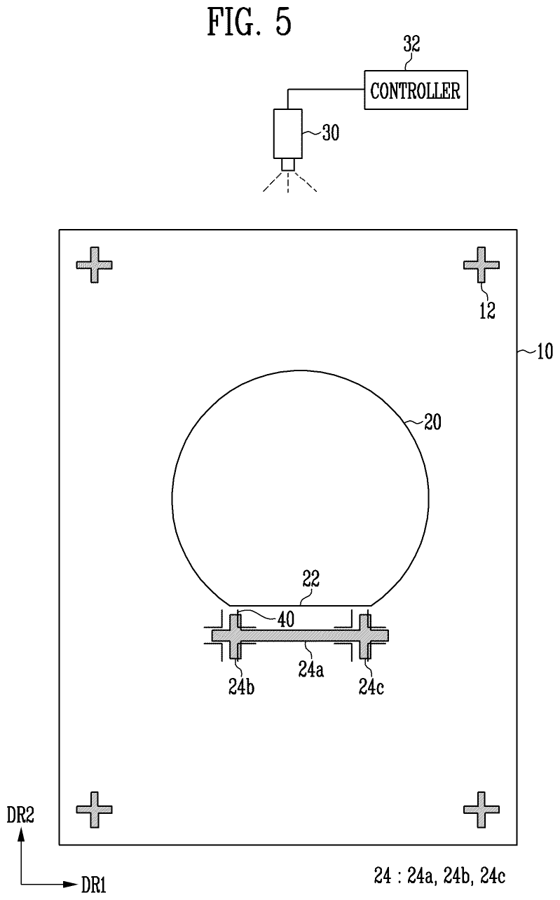

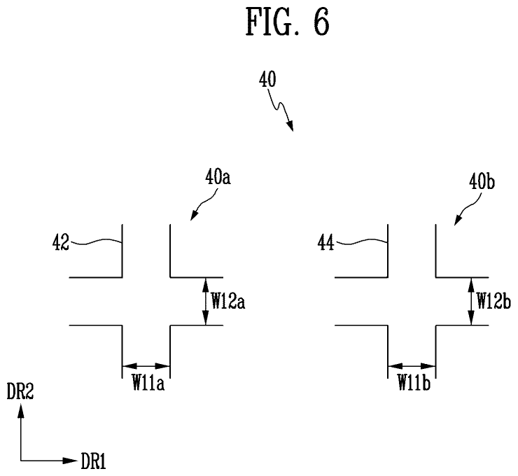

FIGS. 4 and 5 are views illustrating a process of aligning a mask by the alignment apparatus in accordance with an embodiment of the disclosure. FIG. 6 is a view illustrating a second alignment mark printed on the mask.

Referring to FIGS. 4 to 6, a mask (not shown) may be aligned for a process after the wafer 20 is aligned on the glass 10. In an embodiment, a second alignment mark 40 corresponding to the first alignment mark 24 maybe included in the mask. The second alignment mark 40 may be printed on the glass 10, and the controller 32 may align the mask (or the glass 10) by using the second alignment mark 40 printed on the glass 10 and the first alignment mark 24.

As shown in FIG. 6, the second alignment mark 40 may include a 2ath alignment mark 40a and a 2bth alignment mark 40b, each of which inside has a cross or a plus sign shape in a plan view.

The 2ath alignment mark 40a may correspond to the second mark 24b located at the side of the first alignment mark 24. For example, the 2ath alignment mark 40a may include multiple first alignment keys 42 to surround at least a portion of the first mark 24a and at least a portion of the second mark 24b in a plan view. For example, the 2ath alignment mark 40amay include four first alignment keys 42, but the disclosure is not limited thereto. The first alignment keys 42 may respectively have a “L” shape, a shape obtained by rotating the “L” shape by 90 degrees, a shape obtained by rotating the “L” shape by 180 degrees, and a shape obtained by rotating the “L” shape by 270 degrees in a plan view.

The first alignment keys 42 may be arranged such that the first alignment keys 42 form a cross or a plus sign shape in a plan view. A distance W11a between the first alignment keys 42 in the first direction DR1 may be greater than a width of the second mark 24b in the first direction DR1. A distance W12a between the first alignment keys 42 in the second direction DR2 may be greater than a width of the first mark 24a in the second direction DR2. Therefore, the first alignment key 42 may be located at a side of the first alignment mark 24 to surround at least a portion of the first mask 24a and at least a portion of the second mark 24b.

The 2bth alignment mark 40b may correspond to the third mark 24c located at another side of the first alignment mark 24. For example, the 2bth alignment mark 40b may include multiple second alignment keys 44 to surround at least a portion of the first mark 24a and at least a portion of the third mark 24c in a plan view. For example, the 2bth alignment mark 40b may include four second alignment keys 44, but the disclosure is not limited thereto. The second alignment keys 44 may respectively have a “L” shape, a shape obtained by rotating the “L” shape by 90 degrees, a shape obtained by rotating the “L” shape by 180 degrees, and a shape obtained by rotating the “L” shape by 270 degrees.

The second alignment keys 44 may be arranged such that the second alignment keys 44 form a cross or a plus sign shape in a plan view. A distance W11b between the second alignment keys 44 in the first direction DR1 may be greater than a width of the third mark 24cin the first direction DR1. A distance W12b between the second alignment keys 44 in the second direction DR2 may be greater than the width of the first mark 24a in the second direction DR2. Therefore, the second alignment key 44 may be located at the another side of the first alignment mark 24 to surround at least a portion of the first mask 24a and at least a portion of the third mark 24c.

After the second alignment mark 40 is printed on the glass 10, the first alignment mark 24 and the second alignment mark 40 may be photographed using the camera 30, and a photographed image may be supplied to the controller 32. The controller 32 may decide a position of the mask by using the photographed image, and control the position of the glass 10 and/or the mask such that the mask can be located at a desired position. In case that the controller 32 decides that the mask and the glass 10 are not aligned, the controller 32 may move the glass 10 and/or the mask by using a moving means (not shown).

In an embodiment, in case that the first alignment mark 24 overlaps the second alignment mark 40 in the photographed image as shown in FIG. 5 in a plan view, the controller 32 may move the glass 10 and/or the mask such that the first alignment mark 24 is located at the inside of the second alignment mark 40. For example, the controller 32 may align the glass 10 such that, as shown in FIG. 4, the second mark 24b and a portion of the first mark 24a are arranged inside of the 2ath alignment mark 40a and the third mark 24c and another portion of the first mark 24a are arranged inside of the 2bth alignment mark 40b.

In case that the first alignment mark 24 is arranged inside of the second alignment mark 40 in the photographed image, the controller 32 may decide that the mask is aligned at the desired position. To this end, the second alignment mark 40 may be printed on the glass 10 multiple times

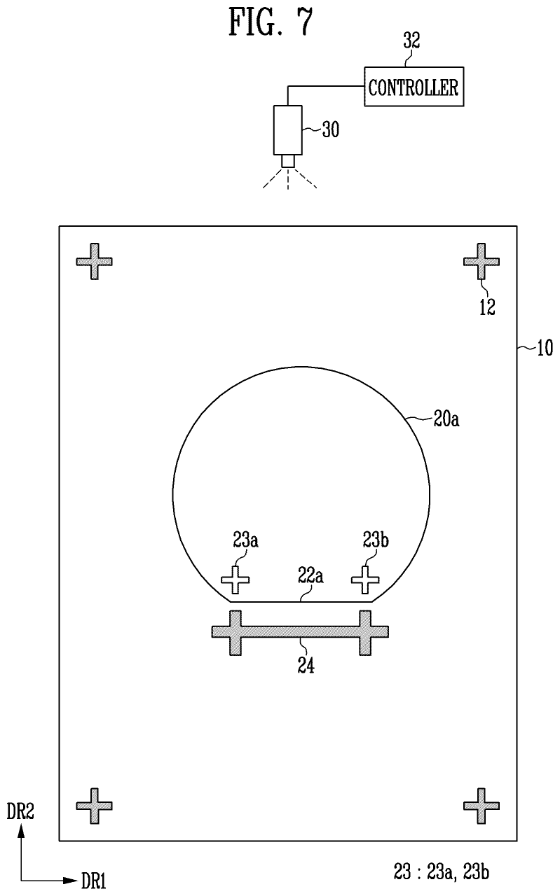

FIG. 7 is a view illustrating an alignment apparatus in accordance with an embodiment of the disclosure. In FIG. 7, portions overlapping those shown in FIG. 1 will be briefly described or omitted.

Referring to FIG. 7, the alignment apparatus in accordance with the embodiment of the disclosure may include a glass 10, a wafer 20a, a camera 30, and a controller 32.

The glass 10 maybe used as a support part on which the wafer 20a is mounted. A fixed alignment mark 12 maybe formed on the glass 10. The fixed alignment mark 12 may 12 maybe used to align a position of the glass 10.

A first alignment mark 24 may be formed on the glass 10. The first alignment mark 24 may be used to align a position of the wafer 20a.

The wafer 20a may be aligned on the glass 10 such that a flat zone 22a is located adjacent to the first alignment mark 24. A transistor layer, a light emitting layer, and a cover layer may be sequentially stacked on the wafer 20a as the wafer 20a goes through various processes, and accordingly, the wafer 20a may be used as a high-resolution light emitting display panel.

A third alignment mark 23 maybe formed at an upper side of (or adjacent to) the flat zone 22a of the wafer 20a. The third alignment mark 23 may include a 3ath alignment mark 23a and a 3bth alignment mark 23b.

The 3ath alignment mark 23a may be located at an upper end of (or adjacent to) a side of the flat zone 22a, and have a cross or a plus sign shape in a plan view. The 3ath alignment mark 23a may overlap a side of the first alignment mark 24 in the second direction DR2.

The 3bth alignment mark 23ba may be located at an upper end of (or adjacent to) another side of the flat zone 22a, and have a cross or a plus sign shape in a plan view. The 3bth alignment mark 23b may overlap another side of the first alignment mark 24 in the second direction DR2.

The wafer 20a may be aligned on the glass 10 by the first alignment mark 24 and the third alignment mark 23. For example, the controller 32 may align the wafer 20a such that a distance between the third alignment mark 23 and the first alignment mark 24 is substantially constant.

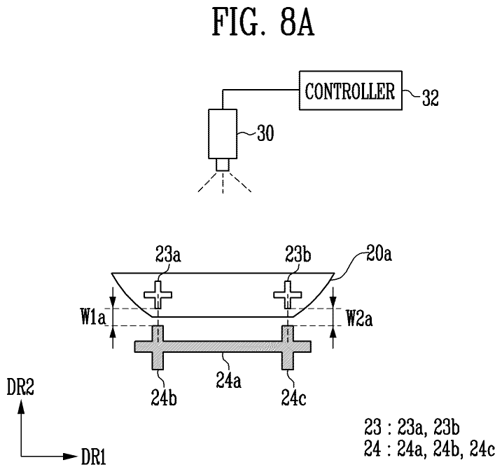

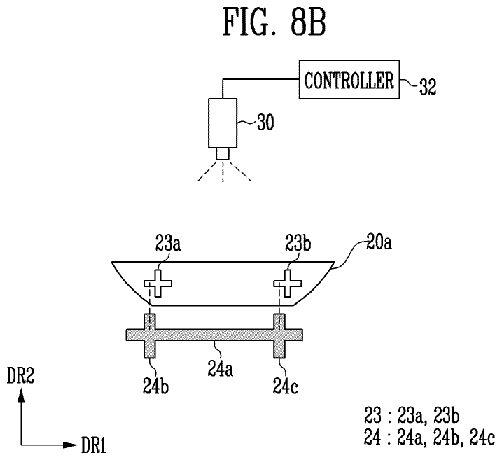

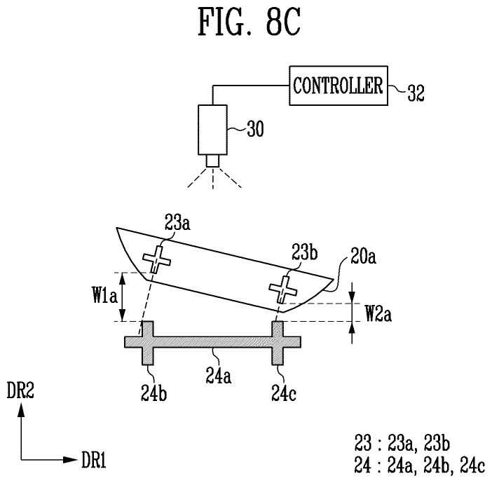

FIGS. 8A to 8C are views illustrating an alignment process of a wafer using the first alignment mark and the third alignment mark. For convenience of description, only a portion of the wafer 20a is illustrated in FIGS. 8A to 8C.

Referring to FIGS. 8A to 8C, the wafer 20a may be aligned on the glass 10 using the first alignment mark 24 and the third alignment mark 23.

After the wafer 20a is mounted on the glass 10, it may be decided whether the wafer 20a is aligned at a desired position by using a photographed image of the camera 30. In an embodiment, the first alignment mark 24 and the third alignment mark 23 maybe photographed by the camera 30, and a photographed image may be supplied to the controller 32. The controller 32 may decide whether central portions of the third alignment mark 23 and central portions of the first alignment mark 24 overlap with each other in the second direction DR2.

The central portion of the first alignment mark 24 maybe a central position of an intersection area of a second mark 24b and a first mark 24a and a central position of an intersection area of a third mark 24c and the first mark 24a. The central portion of the third alignment mark 23 maybe a central position of the 3ath alignment mark 23a and a central position of the 3bth alignment mark 23b.

In an embodiment, the controller 32 may decide whether a central portion of the 3ath alignment mark 23a and a central portion of a side portion of the first alignment mark 24 (e.g., the central portion of the intersection area of the second mark 24b and the first mark 24a) overlap with each other in the second direction DR2. In an embodiment, the controller 32 may decide whether a central portion of the 3bth alignment mark 23b and a central portion of another side portion of the first alignment mark 24 (e.g., the central portion of the intersection area of the third mark 24c and the first mark 24a) overlap with each other in the second direction DR2.

For example, in case that the wafer 20a is not aligned at the desired position, the central portion of the first alignment mark 24 may not overlap the central portion of the third alignment mark 23 in the second direction DR2 as shown in FIG. 8B. The controller 32 may move the wafer 20a (or the glass 10) such that the central portion of the first alignment mark 24 and the central portion of the third alignment mark 23 overlap with each other in the second direction DR2 as shown in FIG. 8A. In case that the central portion of the first alignment mark 24 and the central portion of the third alignment mark 23 overlap with each other in the second direction DR2, the controller 32 may decide that the wafer 20a is aligned at the desired position in the first direction DR1.

In an embodiment, the first alignment mark 24 and the third alignment mark 23 may 23 maybe photographed using the camera 30, and a photographed image may be supplied to the controller 32. The controller 32 may determine whether distances (or widths) W1a and W2a between the first alignment mark 24 and the third alignment mark 23 are within a desired range.

For example, in case that a distance W1a between the 3ath alignment mark 23a and the first alignment mark 24 and a distance W2a between the 3bth alignment mark 23b and the first alignment mark 24 are different from each other as shown in FIG. 8C, the controller 32 may decide that the wafer 20a is not aligned at the desired position. For example, in case that the distance W1a between the 3ath alignment mark 23a and the first alignment mark 24 and the distance W2a between the 3bth alignment mark 23b and the first alignment mark 24 are not within the desired range, the controller 32 may decide that the wafer 20a is not aligned at the desired position.

The controller 32 may move the wafer 20a (or the glass 10) such that the distances W1a and W2a between the first alignment mark 24 and the third alignment mark 23 are within the desired range while being substantially the same. In case that the distances W1a and W2a between the first alignment mark 24 and the third alignment mark 23 are within the desired range while being substantially the same, the controller 32 may decide that the wafer 20a is aligned at the desired position in the second direction DR2.

In the alignment apparatus and the method of alignment using the same in accordance with the disclosure, a wafer may be aligned at a desired position by using a first alignment mark formed on a glass. Also, in accordance with the disclosure, a mask may be aligned at a desired position by using a second alignment mark formed on the mask.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. An alignment apparatus comprising:
a support substrate having a first alignment mark formed thereon; and
a wafer mounted on the support substrate as aligned to the first alignment mark, wherein the first alignment mark includes:
a first mark extending in a first direction;
a second mark extending in a second direction and intersecting the first mark at a side of the first mark; and
a third mark extending in the second direction and intersecting the first mark at another side of the first mark.

2. The alignment apparatus of claim 1, wherein a distance between the second mark and the third mark is less than a length of a flat zone of the wafer in the first direction.

3. The alignment apparatus of claim 1, wherein a length of the first mark in the first direction is greater than a length of a flat zone of the wafer in the first direction.

4. The alignment apparatus of claim 1, further comprising:
a camera that photographs the first alignment mark and the wafer; and
a controller that aligns a position of the wafer by using a photographed image of the camera.

5. The alignment apparatus of claim 4, wherein the controller moves at least one of the wafer and the support substrate such that the second mark and the third mark overlap a flat zone of the wafer in the second direction.

6. The alignment apparatus of claim 4, wherein the controller moves at least one of the wafer and the support substrate such that a distance between the second mark and a flat zone of the wafer and a distance between the third mark and the flat zone of the wafer are within a range and substantially the same.

7. The alignment apparatus of claim 4, further comprising:
a mask including a second alignment mark,
wherein the controller aligns a position of the mask by using the first alignment mark and the second alignment mark.

8. The alignment apparatus of claim 7, wherein the second alignment mark includes:
a 2ath alignment mark that aligns with an area of the first mark and has a cross or a plus sign shape in a plan view; and
a 2bth alignment mark that aligns with another area of the first mark and has a cross or a plus sign shape in a plan view.

9. The alignment apparatus of claim 8, wherein
the 2ath alignment mark includes first alignment keys located to surround the area of the first mark and a portion of the second mark in a plan view, and
the first alignment keys have a “L” shape, a shape obtained by rotating the “L” shape by 90 degrees, a shape obtained by rotating the “L” shape by 180 degrees, and a shape obtained by rotating the “L” shape by 270 degrees in a plan view.

10. The alignment apparatus of claim 9, wherein
a distance between the first alignment keys in the first direction is greater than a width of the second mark in the first direction, and
a distance between the first alignment keys in the second direction is greater than a width of the first mark in the second direction.

11. The alignment apparatus of claim 8, wherein
the 2bth alignment mark includes second alignment keys to be located to surround the another area of the first mark and a portion of the third mark in a plan view, and
the second alignment keys have a “L” shape, a shape obtained by rotating the “L” shape by 90 degrees, a shape obtained by rotating the “L” shape by 180 degrees, and a shape obtained by rotating the “L” shape by 270 degrees in a plan view.

12. The alignment apparatus of claim 11, wherein
a distance between the second alignment keys in the first direction is greater than a width of the third mark in the first direction, and
a distance between the second alignment keys in the second direction is greater than a width of the first mark in the second direction.

13. The alignment apparatus of claim 4, further comprising:
a third alignment mark located at an upper side of a flat zone of the wafer.

14. The alignment apparatus of claim 13, wherein the third alignment mark includes:
a 3ath alignment mark located at an upper side of the flat zone and having a cross or a plus sign shape in a plan view; and
a 3bth alignment mark located at another upper side of the flat zone and having a cross or a plus sign shape in a plan view.

15. The alignment apparatus of claim 14, wherein the controller aligns the wafer by using a distance between the first alignment mark and the third alignment mark and positions of the first alignment mark and the third alignment mark.

16. A method of alignment, the method comprising:
aligning a position of a wafer by using a first alignment mark formed on a support substrate,
wherein the first alignment mark includes:
a first mark extending in a first direction;
a second mark extending in a second direction and intersecting the first mark at a side of the first mark; and
a third mark extending in the second direction and intersecting the first mark at another side of the first mark.

17. The method of claim 16, wherein after the aligning of the position of the wafer,
a distance between a flat zone of the wafer and the first alignment mark is within a range, and
the second mark and the third mark overlap the flat zone in the second direction.

18. The method of claim 16, wherein
a second alignment mark is formed on the wafer, and
the position of the wafer is aligned by using a distance between the first alignment mark and the second alignment mark and positions of the first alignment mark and the second alignment mark.

19. The method of claim 16, wherein
a mask used in a processing process of the wafer is provided, and
the method further comprises:
printing a third alignment mark on the mask; and
aligning a position of the mask by using the first alignment mark and the third alignment mark.

20. The method of claim 16, further comprising:
photographing the first alignment mark and the wafer by using a camera.
